(19) United States
(12) Patent Application Publication
(10) Pub. No.: US 2024/0244785 A1
(43) Pub. Date: Jul. 18, 2024

(54) SERVER APPARATUS

(71) Applicant: PEGATRON CORPORATION, Taipei City (TW)

(72) Inventor: HSIN-KAI CHUANG, TAIPEI CITY (TW)

(21) Appl. No.: 18/379,229

(22) Filed: Oct. 12, 2023

(30) Foreign Application Priority Data
Jan. 13, 2023 (TW) 112101491

(51) Int. Cl. H05K 7/14; H05K 5/02

(52) U.S. Cl. CPC H05K 7/1487; H05K 5/023; H05K 7/1489

(57) ABSTRACT

A server apparatus includes a chassis, a tray disposed in the chassis, and a linkage mechanism. The tray has a first pivotal portion and a second pivotal portion that corresponds in position to the first pivotal portion. The linkage mechanism includes a first linkage member, a second linkage member, and a connection member. The first linkage member has a first end pivotally connected to the first pivotal portion and a second end opposite to the first end. The second linkage member has a third end pivotally connected to the second pivotal portion and a fourth end opposite to the third end. The second linkage member is connected to the second end of the first linkage member through the connection member. When the fourth end receives an external force, the linkage mechanism moves the tray relative to the chassis.

### CROSS-REFERENCE TO RELATED PATENT APPLICATION

This application claims the benefit of priority to Taiwan Patent Application No. 112101491, filed on Jan. 13, 2023. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a server, and more particularly to a server apparatus provided for facilitating pulling or pushing of a tray thereof.

### BACKGROUND OF THE DISCLOSURE

A conventional server includes a chassis and a hard disk disposed in the chassis, and the conventional server has two handles respectively arranged on two opposite sides of the hard disk, so as to facilitate the insertion or removal of the hard disk from the chassis. However, the conventional server requires both hands of a user to operate the two handles, it cannot meet a requirement for one-handed operation.

### SUMMARY OF THE DISCLOSURE

In response to the above-referenced technical inadequacy, the present disclosure provides a server apparatus for effectively improving the issues associated with conventional servers.

In order to solve the above-mentioned problems, one of the technical aspects adopted by the present disclosure is to provide a server apparatus, which includes a chassis, a tray, and a linkage mechanism that is assembled to the tray and that is configured to drive the tray to be moved relative to the chassis. A bottom surface of the tray has a first pivotal portion and a second pivotal portion that corresponds in position to the first pivotal portion, and the tray is disposed in the chassis and is capable of carrying one of hard disks. The linkage mechanism includes a first linkage member, a second linkage member, and a connection member. The first linkage member has a first end and a second end that is opposite to the first end. The first end is pivotally connected to the first pivotal portion. The second linkage member has a third end and a fourth end that is opposite to the third end. The third end is pivotally connected to the second pivotal portion, the second linkage member has a slot arranged between the third end and the fourth end, and a handle is disposed at the fourth end. The connection member connects the second linkage member to the second end of the first linkage member through the slot. When the handle receives a pull force or a push force, the second linkage member moves the first linkage member so as to enable the linkage mechanism to pull out the tray from the chassis or push the tray into the chassis.

Therefore, by the structural configuration of the linkage mechanism, the server apparatus of the present disclosure allows the user to operate the handle of the linkage mechanism with one hand for pulling out the tray from the chassis or pushing the tray into the chassis, so as to enable the server apparatus to meet more diverse requirements.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a server apparatus according to a first embodiment of the present disclosure;

FIG. 2 is a schematic perspective view showing a part of the server apparatus of FIG. 1 from another angle of view;

FIG. 3 is a schematic exploded view of FIG. 2;

FIG. 4 is a schematic cross-sectional view taken along line IV-IV of FIG. 2;

FIG. 5 is a schematic cross-sectional view showing the server apparatus of FIG. 4 after being pulled;

FIG. 6 is a schematic cross-sectional view showing the server apparatus of FIG. 5 after being pulled;

FIG. 7 is a schematic perspective view of FIG. 6;

FIG. 8 is a schematic cross-sectional view showing the server apparatus of FIG. 6 after being pushed;

FIG. 9 is a schematic cross-sectional view showing the server apparatus of FIG. 8 after being pushed;

FIG. 10 is a schematic perspective view of the server apparatus according to a second embodiment of the present disclosure; and

FIG. 11 is a schematic perspective view of the server apparatus according to a third embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

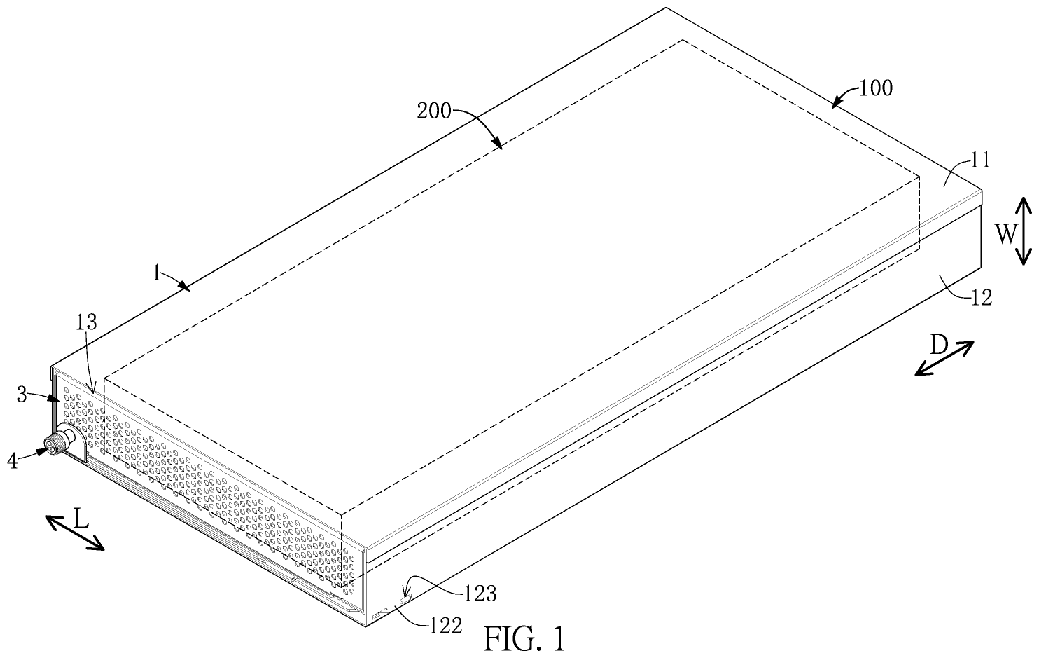

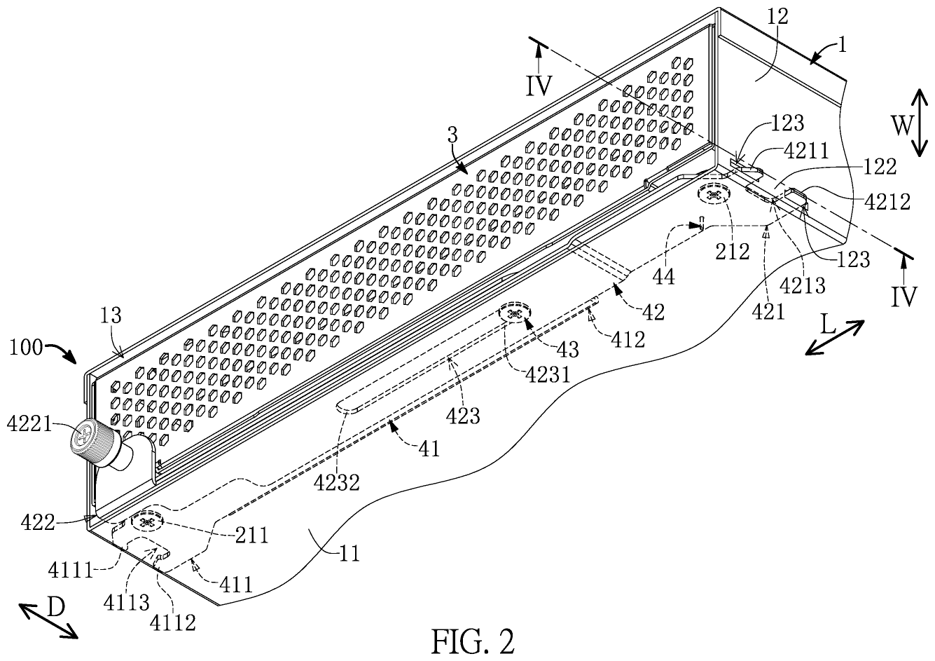

Referring to FIG. 1 to FIG. 9, a first embodiment of the present disclosure is provided. As shown in FIG. 1 to FIG. 3, the present embodiment provides a server apparatus 100, which includes a chassis 1, a tray 2 disposed in the chassis 1, a front plate 3 fixed to the tray 2, and a linkage mechanism 4 that is assembled to the tray 2. The tray 2 is capable of carrying a hard disk 200, the front plate 3 is corresponding in position to an opening 13 of the chassis 1, and the linkage mechanism 4 is configured to drive the tray 2 (and the hard disk 200 disposed thereon) to be moved relative to the chassis 1, but the present disclosure is not limited thereto. For example, in other embodiments of the present disclosure not shown in the drawings, the front plate 3 of the server apparatus 100 can be omitted or can be replaced with other components.

In the present embodiment, the chassis 1 is a hollow cuboid structure and defines a longitudinal direction L, a width direction W perpendicular to the longitudinal direction L, and a depth direction D that is perpendicular to the width direction W and the longitudinal direction L. The chassis 1 includes two broad lateral plates 11 facing toward each other along the width direction W and two narrow lateral plates 12 that face toward each other along the longitudinal direction L. The opening 13 of the chassis 1 in the present embodiment is defined by front ends of the two broad lateral plates 11 and front ends of the two narrow lateral plates 12.

Specifically, the chassis 1 includes a first fulcrum portion 121 and a second fulcrum portion 122 that corresponds in position to the first fulcrum portion 121. In the present embodiment, the first fulcrum portion 121 and the second fulcrum portion 122 are respectively arranged on the two narrow lateral plates 12 and face toward each other along the longitudinal direction L, and the first fulcrum portion 121 and the second fulcrum portion 122 are arranged adjacent to the tray 2 and the front plate 3.

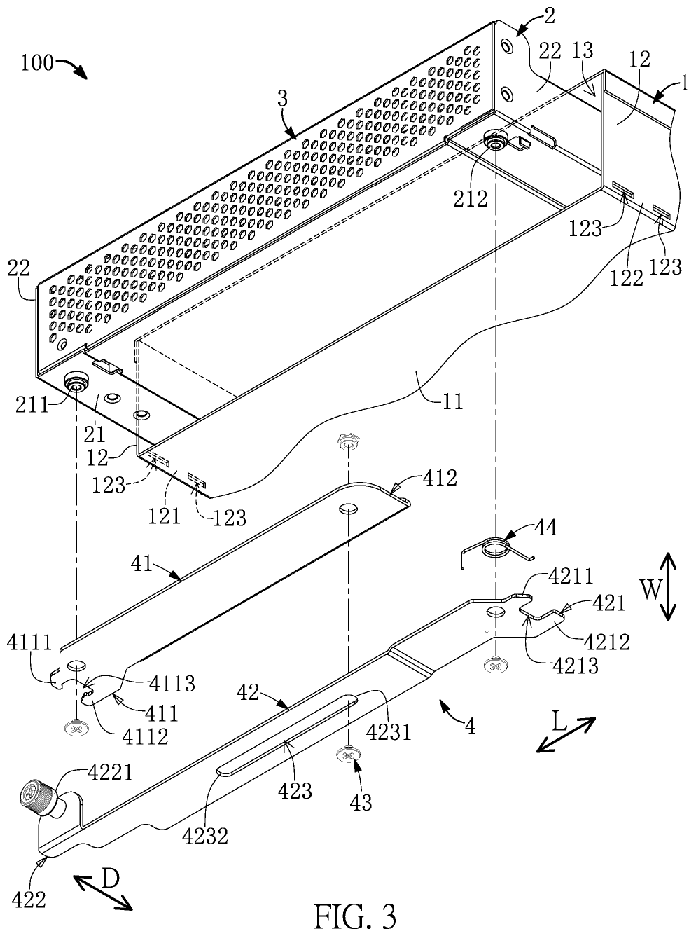

Each of the two narrow lateral plates 12 has two thru-holes 123 arranged along the depth direction D. Moreover, a portion between the two thru-holes 123 of one of the two narrow lateral plates 12 (e.g., the narrow lateral plate 12 shown in a left side of the FIG. 3) is defined as the first fulcrum portion 121, and a portion between the two thru-holes 123 of another one of the two narrow lateral plates 12 (e.g., the narrow lateral plate 12 shown in a right side of the FIG. 3) is defined as the second fulcrum portion 122, but the present disclosure is not limited thereto.

The tray 2 in the present embodiment is formed as a single one-piece structure by bending or punching one metal plate, and the tray 2 has a bottom surface 21 and two lateral surfaces 22 that are perpendicular to the bottom surface 21, but the present disclosure is not limited thereto. The bottom surface 21 of the tray 2 is arranged adjacent to and faces toward one of the two broad lateral plates 11 of the chassis 1, and the two lateral surfaces 22 of the tray 2 are respectively arranged adjacent to and respectively face toward the two narrow lateral plates 12 of the chassis 1.

Moreover, the front plate 3 is fixed to one end of each of the two lateral surfaces 22 of the tray 2 and is perpendicular to the bottom surface 21, such that the hard disk 200 can be received in a space defined by the bottom surface 21, the two lateral surfaces 22, one of the two broad lateral plates 11 of the chassis 1, and the front plate 3.

Specifically, the bottom surface 21 of the tray 2 has a first pivotal portion 211 and a second pivotal portion 212 that corresponds in position to the first pivotal portion 211. The first pivotal portion 211 and the second pivotal portion 212 are respectively arranged adjacent to the first fulcrum portion 121 and the second fulcrum portion 122, and are arranged adjacent to the front plate 3. In other words, the first pivotal portion 211 and the second pivotal portion 212 are respectively arranged at two corners of the bottom surface 21 of the tray 2 that are arranged adjacent to the front plate 3.

The linkage mechanism 4 includes a first linkage member 41, a second linkage member 42, a connection member 43 connecting the first linkage member 41 and the second linkage member 42, and an elastic member 44. In the present embodiment, each of the first linkage member 41 and the second linkage member 42 is an elongated connecting bar, the connection member 43 includes a screw and a corresponding nut, and the elastic member 44 is a spring, but each component of the linkage mechanism 4 can be adjusted or changed according to design requirements and is not limited by the present embodiment.

The first linkage member 41 has a first end 411 and a second end 412 that is opposite to the first end 411, and the second linkage member 42 has a third end 421 and a fourth end 422 that is opposite to the third end 421. The second linkage member 42 has a slot 423 arranged between the third end 421 and the fourth end 422, and a handle 4221 is disposed at the fourth end 422. The connection member 43 connects the second linkage member 42 to the second end 412 of the first linkage member 41 through the slot 423. The handle 4221 is a thumb screw and is detachably locked to the front plate 3. When a user needs to pull out the tray 2 from the chassis 1, the user can rotate the thumb screw for releasing thereof and then pull out the tray 2 through the thumb screw. When the tray 2 is pushed into the chassis 1 and does not need to be pulled out, the user can rotate the thumb screw to be locked to the front plate 3.

In the present embodiment, the slot 423 is elongated and has a first position 4231 and a second position 4232 that is different from (or opposite to) the first position 4231. The first position 4231 is located adjacent to the third end 421, and the second position 4232 is located away from the third end 421. The connection member 43 is fixed to the second end 412 of the first linkage member 41 through the slot 423, and the connection member 43 is slidable between the first position 4231 and the second position 4232 of the slot 423.

Moreover, the first linkage member 41 is pivotally connected to the first pivotal portion 211 of the tray 2 along the width direction W through the first end 411, and the second linkage member 42 is pivotally connected to the second pivotal portion 212 of the tray 2 along the width direction W through the third end 421. As shown in FIG. 3, the third end 421 of the second linkage member 42 is disposed on the second pivotal portion 212 of the tray 2 through the elastic member 44, so that when the second linkage member 42 is moved relative to the tray 2, the elastic member 33 is pressed and deformed to provide an elastic force.

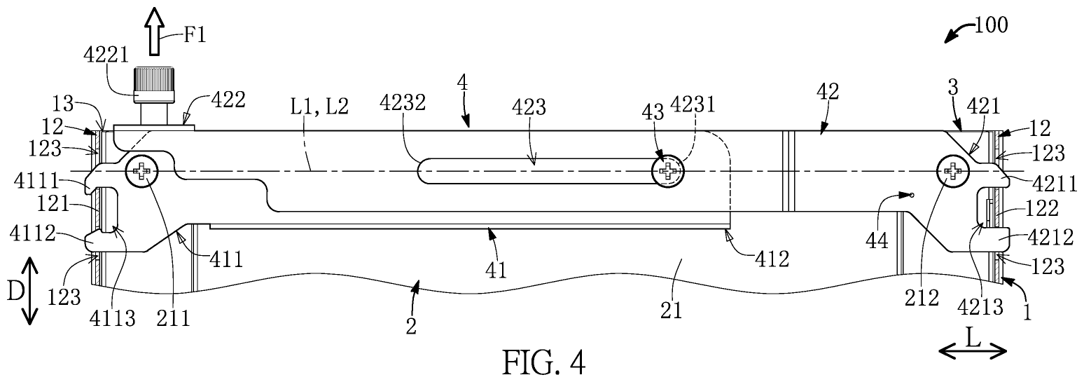

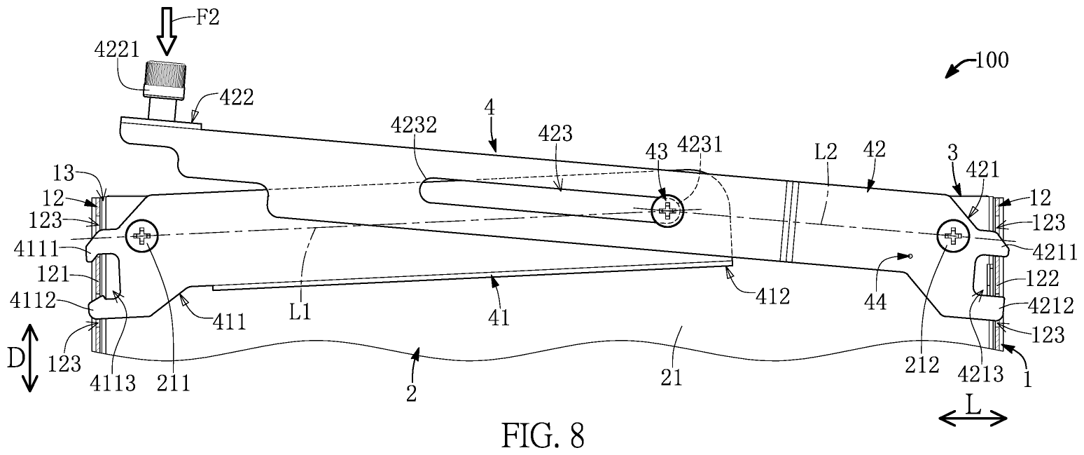

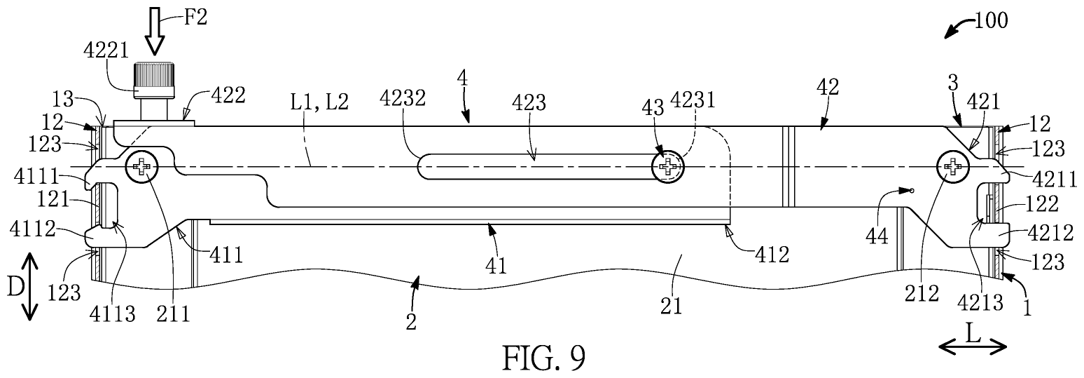

In summary, when the handle 4221 receives a pull force F1 (shown in FIG. 4 to FIG. 7) or a push force F2 (shown in FIG. 8 and FIG. 9) along the depth direction D, the second linkage member 42 moves the first linkage member 41 so as to enable the linkage mechanism 4 to pull out the tray 2 from the chassis 1 or push the tray 2 into the chassis 1. The elastic member 44 can provide the elastic force having a direction the same as that of the pull force F1, thereby facilitating removal of the tray 2 from the chassis 1 for a user.

Accordingly, by the structural configuration of the linkage mechanism 4, the server apparatus 100 of the present embodiment allows the user to operate the handle 4221 of the linkage mechanism 4 with one hand for pulling out the tray 2 from the chassis 1 or pushing the tray 2 into the chassis 1, so as to enable the server apparatus 100 to meet more diverse requirements.

As shown in FIG. 4 to FIG. 7, when the handle 4221 receives the pull force F1, the first linkage member 41 is rotated along a counterclockwise direction by taking the first fulcrum portion 121 as a fulcrum, the second linkage member 42 is rotated along a clockwise direction by taking the second fulcrum portion 122 as a fulcrum, and the connection member 43 is moved along the slot 423 from the first position 4231 toward the second position 4232.

Moreover, as shown in FIG. 8 and FIG. 9, when the handle 4221 receives the push force F2, the first linkage member 41 is rotated along a clockwise direction by taking the first fulcrum portion 121 as a fulcrum, the second linkage member 42 is rotated along a counterclockwise direction by taking the second fulcrum portion 122 as a fulcrum, and the connection member 43 is moved along the slot 423 from the second position 4232 toward the first position 4231.

It should be noted that, in order to enable the linkage mechanism 4 to more smoothly pull out the tray 2 from the chassis 1 or push the tray 2 into the chassis 1, the linkage mechanism 4 preferably includes at least part of the following structural features, but the present disclosure is not limited thereto.

As shown in FIG. 4 to FIG. 6, the first end 411 of the first linkage member 41 having a C-shaped notch 4113 can be engaged with the first fulcrum portion 121, the third end 421 of the second linkage member 42 having a U-shaped notch 4213 can be engaged with the second fulcrum portion 122, and the first linkage member 41 and the second linkage member 42 are rotatable by respectively taking the first fulcrum portion 121 and the second fulcrum portion 122 to be two fulcrums, so as to pull out the tray 2 from the chassis 1 or push the tray 2 into the chassis 1.

Specifically, each of the first end 411 of the first linkage member 41 and the third end 421 of the second linkage member 42 includes a first tooth portion 4111, 4211 and a second tooth portion 4112, 4212 that is arranged adjacent to the first tooth portion 4111, 4211. In the present embodiment, the first tooth portion 4111 and the second tooth portion 4112 of the first linkage member 41 jointly define the C-shaped notch 4113, and the first tooth portion 4211 and the second tooth portion 4212 of the second linkage member 42 jointly define the U-shaped notch 4213. Moreover, in any one of the first linkage member 41 and the second linkage member 42, the first tooth portion 4111, 4211 and the second tooth portion 4112, 4212 are arranged along the depth direction D, and the second tooth portion 4112, 4212 is arranged away from the front plate 3 with respect to the first tooth portion 4111, 4211.

Accordingly, the server apparatus 100 of the present embodiment can be provided with the structural difference between the first end 411 and the third end 421 (e.g., shapes of the first tooth portion 4111 and the second tooth portion 4112 of the first linkage member 41 are different from shapes of the first tooth portion 4211 and the second tooth portion 4212 of the second linkage member 42) so as to facilitate the rotation compensation between the first linkage member 41 and the second linkage member 42 during the asynchronous rotation process, but the present disclosure is not limited thereto.

In other words, the first pivotal portion 211 of the tray 2, the first tooth portion 4111 of the first linkage member 41, and the connection member 43 are arranged along a first axis L1, and the second pivotal portion 212 of the tray 2, the first tooth portion 4211 of the second linkage member 42, and the connection member 43 are arranged along a second axis L2.

As shown in FIG. 4, when the tray 2 is located in the chassis 1, the connection member 43 is located at the first position 4231 of the slot 423, the first axis L1 overlaps with the second axis L2, the first linkage member 41 is engaged with the first fulcrum portion 121 through the C-shaped notch 4113, the second linkage member 42 is engaged with the second fulcrum portion 122 through the U-shaped notch 4213, and the first tooth portion 4111, 4211 and the second tooth portion 4112, 4212 of any one of the first linkage member 41 and the second linkage member 42 respectively pass through the two thru-holes 123 of the corresponding narrow lateral plate 12.

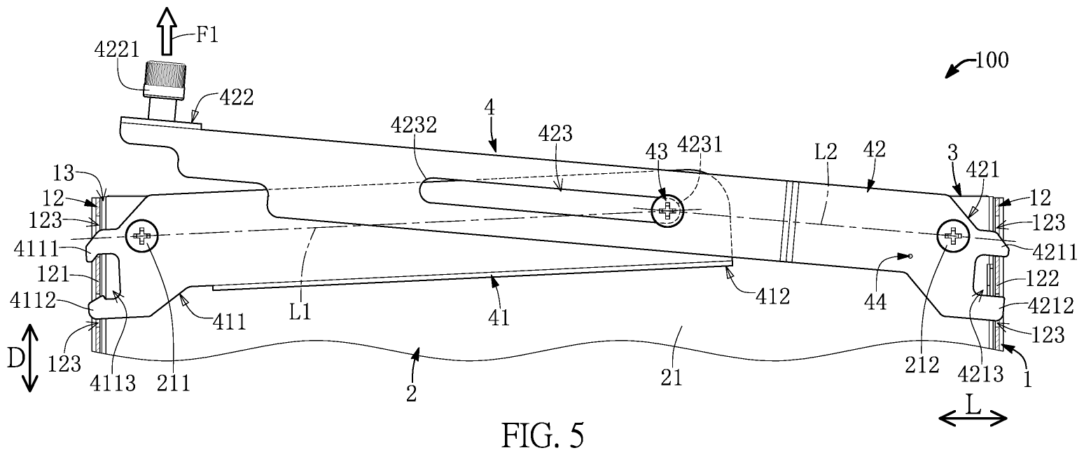

As shown in FIG. 5, when the handle 4221 receives the pull force F1, the connection member 43 is moved along the slot 423 from the first position 4231 toward the second position 4232, the first tooth portions 4111, 4211 of the first linkage member 41 and the second linkage member 42 respectively abut against the first fulcrum portion 121 and the second fulcrum portion 122 to pull out the tray 2 from the chassis 1 along the depth direction D.

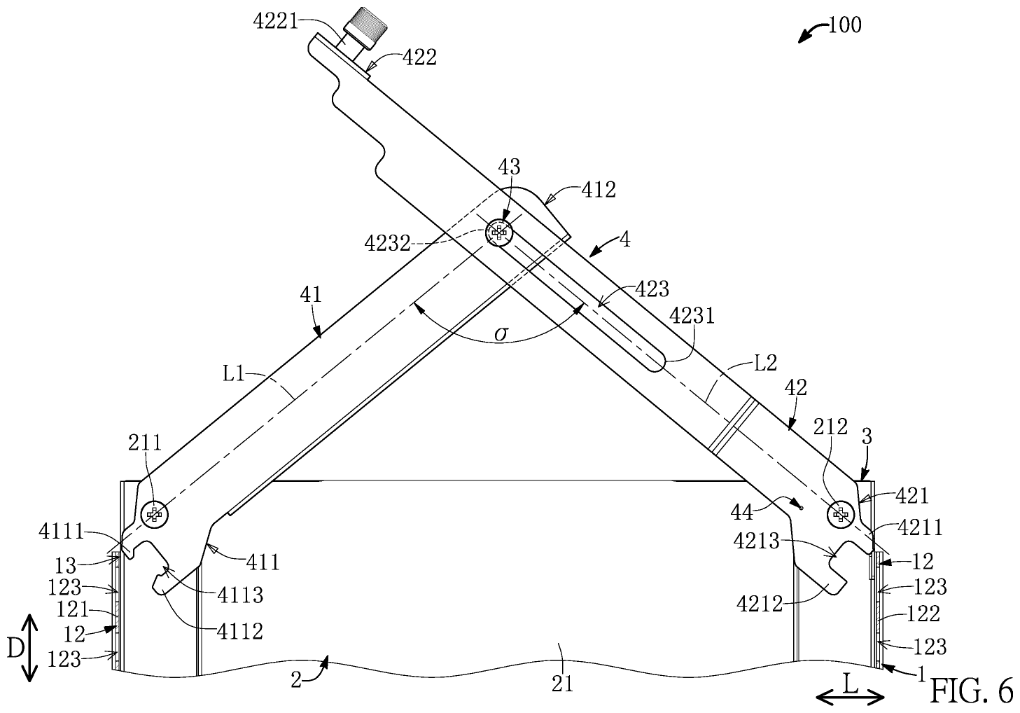

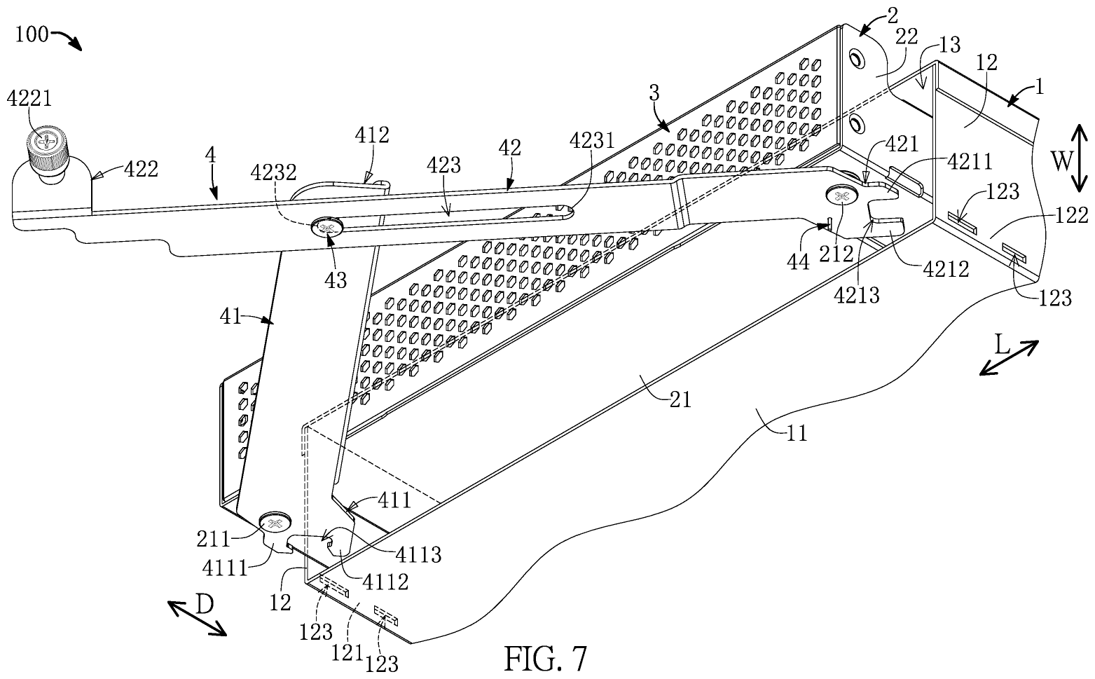

As shown in FIG. 6 and FIG. 7, when the tray 2 is located outside of the chassis 1, the connection member 43 is located at the second position 4232 of the slot 423, an angle σ formed between the first axis L1 and the second axis L2 is less than 180 degrees (e.g., the angle σ being preferably within a range from 101 degrees to 104 degrees), and the first tooth portion 4111, 4211 and the second tooth portion 4112, 4212 of any one of the first linkage member 41 and the second linkage member 42 are separated from the chassis 1.

As shown in FIG. 8 and FIG. 9, when the handle 4221 receives the push force F2, the connection member 43 is moved along the slot 423 from the second position 4232 toward the first position 4231, the second tooth portions 4112, 4212 of the first linkage member 41 and the second linkage member 42 respectively abut against the first fulcrum portion 121 and the second fulcrum portion 122 to push the tray 2 into the chassis 1 along the depth direction D.

### Second Embodiment

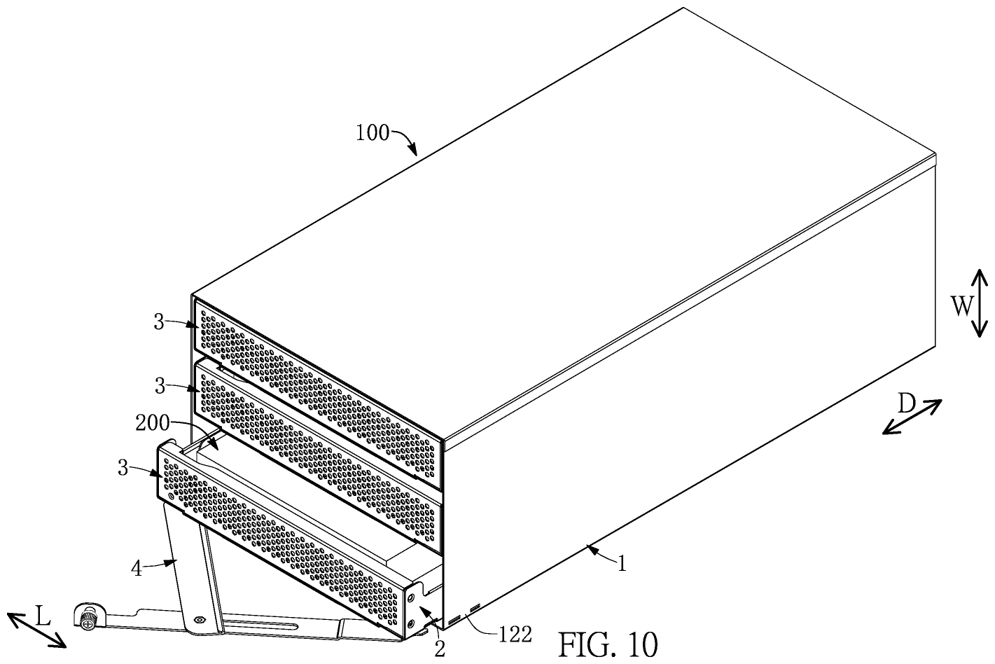

Referring to FIG. 10, a second embodiment of the present disclosure, which is similar to the first embodiment of the present disclosure, is provided. For the sake of brevity, descriptions of the same components in the first and second embodiments of the present disclosure will be omitted herein, and the following description only discloses different features between the first and second embodiments.

In the present embodiment, a quantity of the first fulcrum portion (not shown in the drawings) in the chassis 1 is more than one, and a quantity of the second fulcrum portion 122 in the chassis 1 is more than one. Each of the first fulcrum portions faces toward one of the second fulcrum portions 122 along the longitudinal direction L.

Moreover, a quantity of the tray 2 in the server apparatus 100 is more than one, and the trays 2 are disposed in the chassis 1 in a stacked manner and are capable of respectively carrying hard disks 200. Each of the trays 2 is corresponding in position to one of the first fulcrum portions and the corresponding second fulcrum portion 122, and the linkage mechanism 4 is assembled to one of the trays 2.

### Third Embodiment

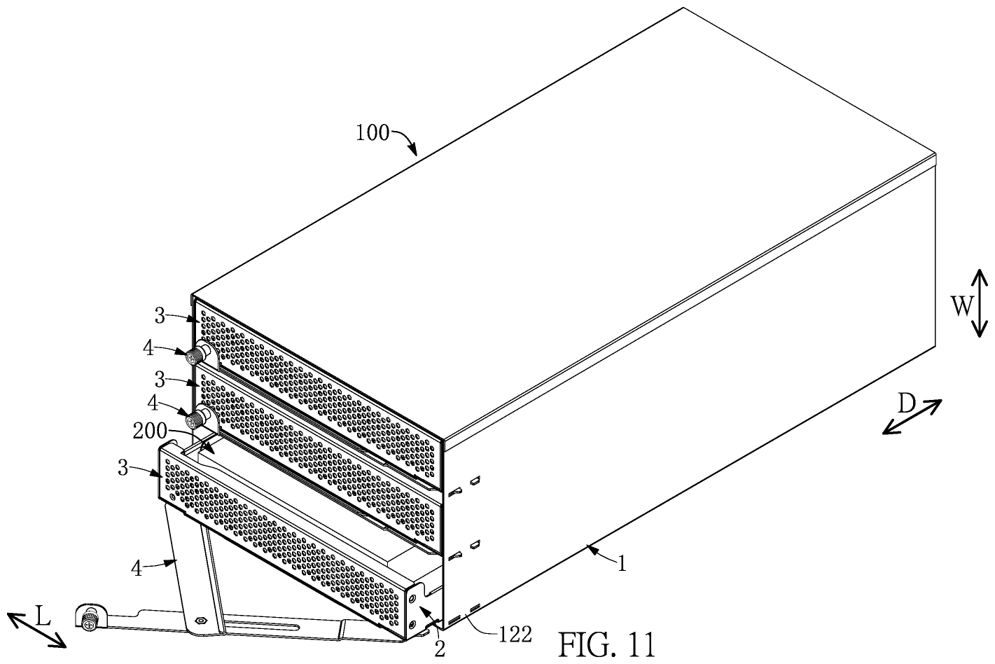

Referring to FIG. 11, a third embodiment of the present disclosure, which is similar to the second embodiment of the present disclosure, is provided. For the sake of brevity, descriptions of the same components in the second and third embodiments of the present disclosure will be omitted herein, and the following description only discloses different features between the second and third embodiments.

In the present embodiment, a quantity of the linkage mechanism 4 in the server apparatus 100 is more than one, and the linkage mechanisms 4 are respectively assembled to the trays 2.

### Beneficial Effects of the Embodiments

In conclusion, by the structural configuration of the linkage mechanism, the server apparatus of the present disclosure allows the user to operate the handle of the linkage mechanism with one hand for pulling out the tray from the chassis or pushing the tray into the chassis, so as to enable the server apparatus to meet more diverse requirements.

Moreover, the server apparatus of the present disclosure can be provided with the structural difference between the first end of the first linkage member and the third end of the second linkage member to facilitate the rotation compensation during the asynchronous rotation process.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A server apparatus, comprising:
a chassis;
a tray having a bottom surface, wherein the bottom surface has a first pivotal portion and a second pivotal portion that corresponds in position to the first pivotal portion, and the tray is disposed in the chassis and is capable of carrying one of hard disks; and
a linkage mechanism assembled to the tray and configured to drive the tray to be moved relative to the chassis, wherein the linkage mechanism includes:
a first linkage member having a first end and a second end that is opposite to the first end, wherein the first end is pivotally connected to the first pivotal portion;
a second linkage member having a third end and a fourth end that is opposite to the third end, wherein the third end is pivotally connected to the second pivotal portion, the second linkage member has a slot arranged between the third end and the fourth end, and a handle is disposed at the fourth end; and
a connection member that connects the second linkage member to the second end of the first linkage member through the slot;
wherein, when the handle receives a pull force or a push force, the second linkage member moves the first linkage member so as to enable the linkage mechanism to pull out the tray from the chassis or push the tray into the chassis.

2. The server apparatus according to claim 1, wherein the chassis includes a first fulcrum portion and a second fulcrum portion that corresponds in position to the first fulcrum portion, and each of the first end of the first linkage member and the third end of the second linkage member includes a first tooth portion and a second tooth portion that is arranged adjacent to the first tooth portion; wherein, when the handle receives the pull force, the first tooth portions of the first linkage member and the second linkage member respectively abut against the first fulcrum portion and the second fulcrum portion to pull out the tray from the chassis; and wherein, when the handle receives the push force, the second tooth portions of the first linkage member and the second linkage member respectively abut against the first fulcrum portion and the second fulcrum portion to push the tray into the chassis.

3. The server apparatus according to claim 2, wherein shapes of the first tooth portion and the second tooth portion of the first linkage member are different from that of the second linkage member.

4. The server apparatus according to claim 2, wherein the first pivotal portion of the tray, the first tooth portion of the first linkage member, and the connection member are arranged along a first axis, and the second pivotal portion of the tray, the first tooth portion of the second linkage member, and the connection member are arranged along a second axis; wherein, when the tray is located in the chassis, the first axis overlaps with the second axis; and wherein, when the tray is located outside of the chassis, an angle formed between the first axis and the second axis is less than 180 degrees.

5. The server apparatus according to claim 2, wherein the first tooth portion and the second tooth portion of the first linkage member jointly define a C-shaped notch, and the first tooth portion and the second tooth portion of the second linkage member jointly define a U-shaped notch; wherein the first linkage member is engaged with the first fulcrum portion through the C-shaped notch, and the second linkage member is engaged with the second fulcrum portion through the U-shaped notch; and wherein the first linkage member and the second linkage member are rotatable by respectively taking the first fulcrum portion and the second fulcrum portion as fulcrums, so as to pull out the tray from the chassis or push the tray into the chassis.

6. The server apparatus according to claim 5, wherein, when the handle receives the pull force, the first linkage member is rotated along a counterclockwise direction by taking the first fulcrum portion as a fulcrum, and the second linkage member is rotated along a clockwise direction by taking the second fulcrum portion as a fulcrum.

7. The server apparatus according to claim 5, wherein, when the handle receives the push force, the first linkage member is rotated along a clockwise direction by taking the first fulcrum portion as a fulcrum, and the second linkage member is rotated along a counterclockwise direction by taking the second fulcrum portion as a fulcrum.

8. The server apparatus according to claim 5, wherein, in the chassis, a quantity of the first fulcrum portion is more than one, a quantity of the second fulcrum portion is more than one, and the first fulcrum portions respectively correspond in position to the second fulcrum portions; wherein a quantity of the tray in the server apparatus is more than one, and the trays are disposed in the chassis in a stacked manner and are capable of respectively carrying the hard disks; wherein a quantity of the linkage mechanism in the server apparatus is more than one, and the linkage mechanisms are respectively assembled to the trays; and wherein each of the trays corresponds in position to one of the first fulcrum portions and the corresponding second fulcrum portion.

9. The server apparatus according to claim 1, further comprising a front plate fixed to the tray; wherein the first pivotal portion and the second pivotal portion are arranged adjacent to the front plate; and wherein, when the tray is located in the chassis, the handle is detachably locked to the front plate.

10. The server apparatus according to claim 1, wherein the slot is elongated and has a first position and a second position that is different from the first position, and the connection member is slidable between the first position and the second position.

11. The server apparatus according to claim 1, wherein the linkage mechanism includes an elastic member, and the third end of the second linkage member is disposed on the second pivotal portion of the tray through the elastic member that provides an elastic force having a direction that is same as that of the pull force.
